(19) United States
(12) Patent Application Publication
(10) Pub. No.: US 2024/0145538 A1
(43) Pub. Date: May 2, 2024

(54) TRANSISTORS WITH ASYMMETRIC SOURCE/DRAIN REGIONS

(71) Applicant: International Business Machines Corporation, Armonk, NY (US)

(72) Inventors: Min Gyu Sung, Latham, NY (US); Ruilong Xie, Niskayuna, NY (US); Chanro Park, Clifton Park, NY (US); Kangguo Cheng, Schenectady, NY (US); Julien Frougier, Albany, NY (US)

(21) Appl. No.: 17/974,047

(22) Filed: Oct. 26, 2022

(51) Int. Cl. H01L 29/06; H01L 23/48; H01L 27/092; H01L 29/08; H01L 29/786

(52) U.S. Cl. CPC H01L 29/0673; H01L 23/481; H01L 27/0924; H01L 29/0847; H01L 29/78696

(57) ABSTRACT

A semiconductor structure comprises a source/drain region, a spacer layer on a first side of the source/drain region, a contact on a top surface of the source/drain region, and a via connected to a portion of the contact at a second side of the source/drain region, the second side of the source/drain region being opposite the first side of the source/drain region.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost.

### SUMMARY

Embodiments of the invention provide techniques for forming transistors with asymmetric source/drain regions.

In one embodiment, a semiconductor structure comprises a source/drain region, a spacer layer on a first side of the source/drain region, a contact on a top surface of the source/drain region, and a via connected to a portion of the contact at a second side of the source/drain region, the second side of the source/drain region being opposite the first side of the source/drain region.

In another embodiment, a semiconductor structure comprises a first transistor comprising a first source/drain region, a second transistor comprising a second source/drain region, and a spacer layer on a first side of the first source/drain region and a first side of the second source/drain region. A second side of the first source/drain region extends towards the first side of the second source/drain region.

In another embodiment, an integrated circuit comprises a nanosheet transistor structure comprising two or more nanosheet transistors, a first one of the two or more nanosheet transistors comprising a first source/drain region and a second one of the two or more nanosheet transistors comprising a second source/drain region, the second nanosheet transistor being adjacent the first nanosheet transistor, and a spacer layer on a first side of the first source/drain region and a first side of the second source/drain region. A second side of the first source/drain region extends towards the first side of the second source/drain region.

These and other features and advantages of embodiments described herein will become more apparent from the accompanying drawings and the following detailed description.

### BRIEF DESCRIPTION OF THE DRAWINGS

FIGS. 1A-1E show views of a nanosheet transistor structure following formation of a spacer, according to an embodiment of the invention.

FIGS. 2A-2E show views of the structure of FIGS. 1A-1E following etching of a portion of the spacer, according to an embodiment of the invention.

FIGS. 3A-3E show views of the structure of FIGS. 2A-2E following etching of exposed portions of a nanosheet stack, according to an embodiment of the invention.

FIGS. 4A-4F show views of the structure of FIGS. 3A-3E following formation of first source/drain regions, according to an embodiment of the invention.

FIGS. 5A and 5B show views of the structure of FIGS. 4A-4F following formation of second source/drain regions, according to an embodiment of the invention.

FIGS. 6A-6D show views of the structure of FIGS. 1A-1E following etching of a portion of the spacer such that the spacer remains on sidewalls of nanosheet stacks between gate structures, according to an embodiment of the invention.

FIG. 7 shows a view of the structure of FIGS. 6A-6D following an angled etch which removes portions of the spacer from one side of the nanosheet stacks between the gate structures, according to an embodiment of the invention.

FIG. 8 shows a view of the structure of FIG. 7 following epitaxial growth of asymmetric source/drain regions, according to an embodiment of the invention.

FIG. 9A shows a view of the structure of FIG. 8 with asymmetric source/drain regions following formation of contacts, according to an embodiment of the invention.

FIG. 9B shows a view of the structure of FIGS. 5A and 5B with symmetric source/drain regions following formation of contacts, according to an embodiment of the invention.

FIG. 10 depicts an integrated circuit comprising one or more nanosheet transistor structures with asymmetric source/drain regions, according to an embodiment of the invention.

### DETAILED DESCRIPTION

Illustrative embodiments of the invention may be described herein in the context of illustrative methods for forming transistors with asymmetric source/drain regions, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves removing sacrificial layers, which may be formed of silicon germanium (SiGe), between sheets of channel material, which may be formed of silicon (Si).

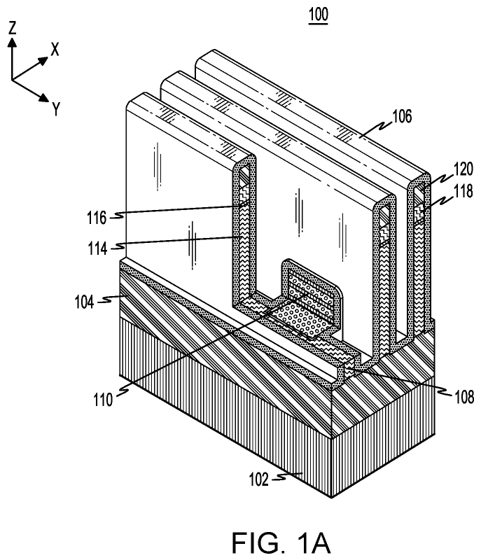

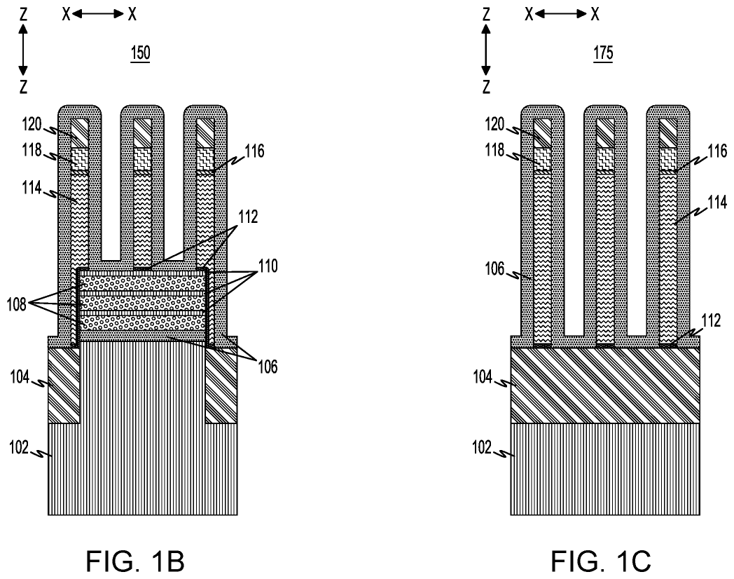

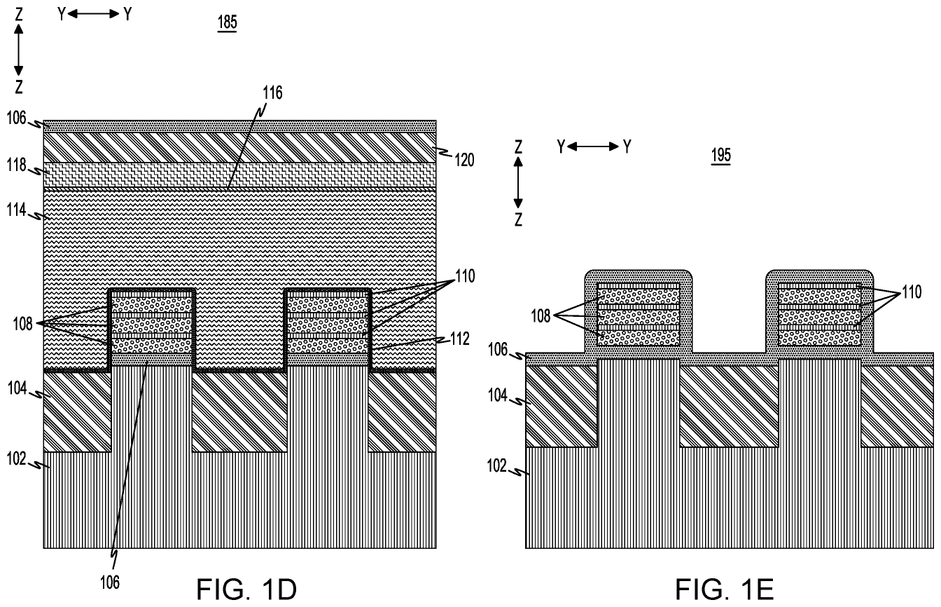

FIG. 1A shows a perspective view 100 of a nanosheet transistor structure, and FIGS. 1B, 1C, 1D and 1E shows respective cross-sectional views 150, 175, 185 and 195 of the nanosheet transistor structure. The cross-sectional views 150 of FIG. 1B and 175 of FIG. 1C are taken in the X direction across where gate regions will be formed. More particularly, the cross-sectional view 150 of FIG. 1B represents an nFET or pFET cut view across where the gate regions will be formed and the cross-sectional view 175 of FIG. 1C is taken in the space between adjacent nanosheet stacks (e.g., which may be between a first nanosheet stack used for an nFET device and a second nanosheet stack used for a pFET device, or between first and second nanosheet stacks which are both used for nFET or pFET devices). The cross-sectional views 185 of FIG. 1D and 195 of FIG. 1E are taken in the Y direction. More particularly, the cross-sectional view 185 of FIG. 1D is taken along where a gate region will be formed, while the cross-sectional view 195 of FIG. 1E is taken between where two gate regions will be formed (e.g., in regions where source/drain regions will be formed).

The nanosheet transistor structure of FIGS. 1A-1E includes a substrate 102, shallow trench isolation (STI) regions 104, a spacer layer 106, sacrificial layers 108, nanosheet channel layers 110, a blocking oxide layer 112, a dummy gate layer 114, an interlayer (IL) oxide layer 116, a gate hard mask (HM) layer 118, and a HM oxide layer 120.

The substrate 102 may be formed of any suitable semiconductor structure, including various silicon-containing materials including but not limited to Si, SiGe, silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc.

A nanosheet stack is formed over the substrate 102, where the nanosheet stack includes the sacrificial layers 108 and the nanosheet channel layers 110. The sacrificial layers 108 may be formed of SiGe or another suitable material that can be etched selective to the material of the substrate 102. The sacrificial layers 108 may each have a thickness (in direction Z) in the range of 6-15 nm. The nanosheet channel layers 110 may be formed of Si or another suitable material (e.g., a material similar to that used for the substrate 102). Each of the nanosheet channel layers 110 may have a thickness (in direction Z) in the range of 4-10 nm.

The STI regions 104 may be formed of a dielectric material such as silicon dioxide (SiO₂), silicon oxycarbide (SiOC), silicon oxynitride (SiON), etc. The STI regions 104 may have a height (in direction Z) in the range of 20 to 100 nm. The STI regions 104 may be formed by patterning a mask layer over the nanosheet stack, then etching exposed portions of the nanosheet stack and into a portion of the substrate 102.

The blocking oxide layer 112 is formed over the nanosheet stack and the STI regions 104 in portions of the structure where gate structures are to be formed. The blocking oxide layer 112 may comprise an oxide material such as SiO₂, and acts as an etch stop during removal of the dummy gate layer 114. The blocking oxide layer 112 may have a uniform thickness in the range of 2-10 nm.

The dummy gate layer 114 may comprise polysilicon or another suitable material such as amorphous silicon (a-Si). The dummy gate layer 114 may have a thickness (in direction X) in the range of 10-100 nm, and a height (in direction Z) in the range of 100-200 nm.

The IL oxide layer 116 may be formed of an oxide such as SiO₂. The IL oxide layer 116 may have a height (in direction Z) in the range of 1-5 nm.

The gate HM layer 118 may be formed of a nitride material such as silicon nitride (SiN), silicon boron carbide nitride (SiBCN), silicon oxycarbonitride (SiOCN), etc. The gate HM layer 118 may have a height (in direction Z) in the range of 10-100 nm.

The HM oxide layer 120 may be formed of Sift or another suitable material. The HM oxide layer 120 may have a height (in direction Z) in the range of 10-100 nm.

Material for the blocking oxide layer 112 may initially be formed over the whole structure, followed by material for the dummy gate layer 114 and the IL oxide layer 116. The gate HM layer 118 and HM oxide layer 120 may then be patterned over the material of the IL oxide layer 116. Exposed portions of the material of the IL oxide layer 116, the dummy gate layer 114 and the blocking oxide layer 112 are then etched to result in the structure shown in FIGS. 1A-1E.

The spacer layer 106 may be formed of a low-k nitride material such as SiN, SiBCN, SiOCN, etc. The spacer layer 106 may have a uniform thickness in the range of 5-20 nm.

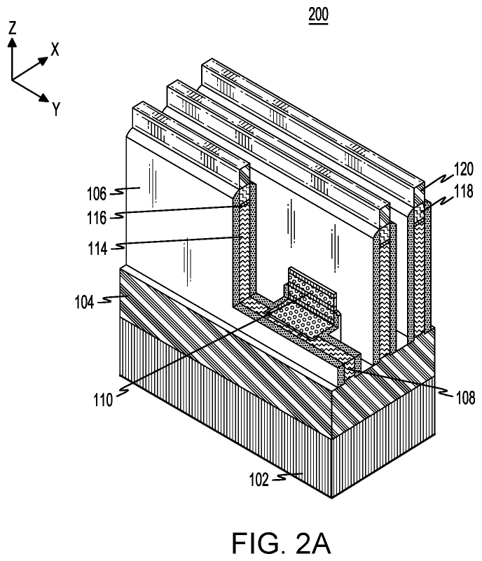

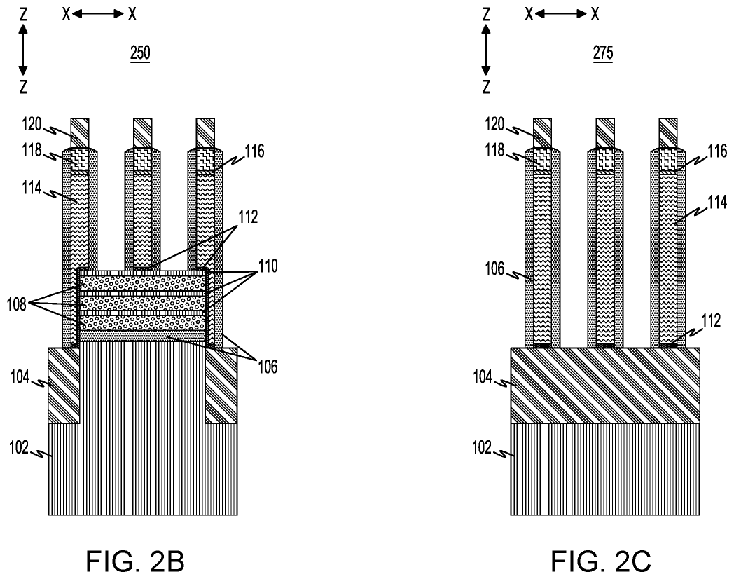

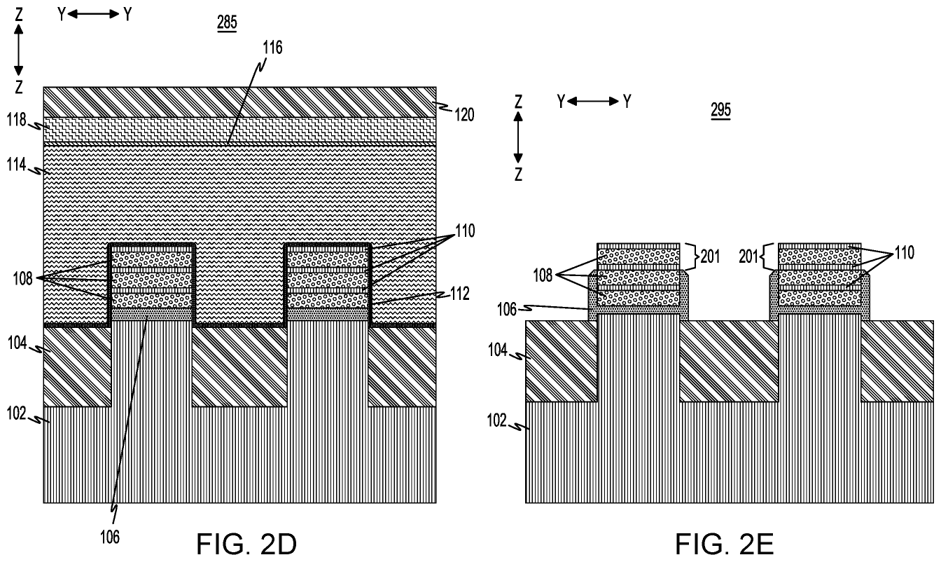

FIG. 2A shows a perspective view 200 of the structure of FIGS. 1A-1E following etching of the spacer layer 106, and FIGS. 2B, 2C, 2D and 2E show respective cross-sectional views 250, 275, 285 and 295 of the structure of FIGS. 1A-1E following the etching of the spacer layer 106. The cross-sectional views 250 of FIG. 2B and 275 of FIG. 2C are taken in the X direction. More particularly, the cross-sectional view 250 of FIG. 2B represents an nFET or pFET cut view, and the cross-sectional view 275 of FIG. 2C is taken in the space between two nanosheet stacks (e.g., which may be between a first nanosheet stack used for an nFET device and a second nanosheet stack used for a pFET device, or between first and second nanosheet stacks which are both used for nFET or pFET devices). The cross-sectional views 285 of FIG. 2D and 295 of FIG. 2E are taken in the Y direction. More particularly, the cross-sectional view 285 of FIG. 2D is taken along where a gate region is formed, while the cross-sectional view 295 of FIG. 2E is taken between where two gate regions will be formed (e.g., in regions where source/drain regions will be formed).

As shown in FIGS. 2A-2E, the spacer layer 106 is etched such that sidewalls of the HM oxide layer 120 is exposed, along with tops of the nanosheet stacks between the gate regions. Portions of the spacer layer 106 on sidewalls of the nanosheet stacks are also etched, as shown in FIG. 2E in regions 201.

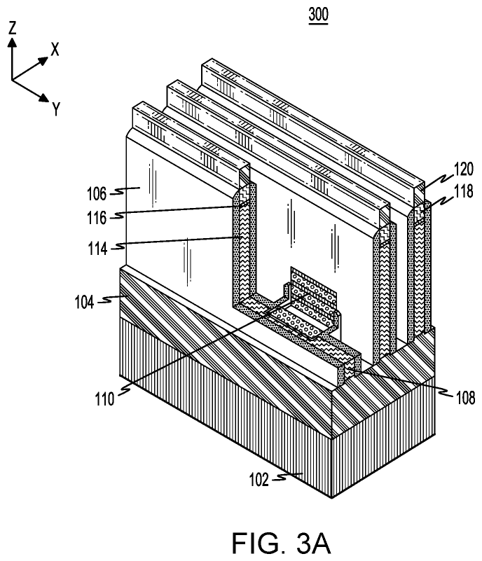

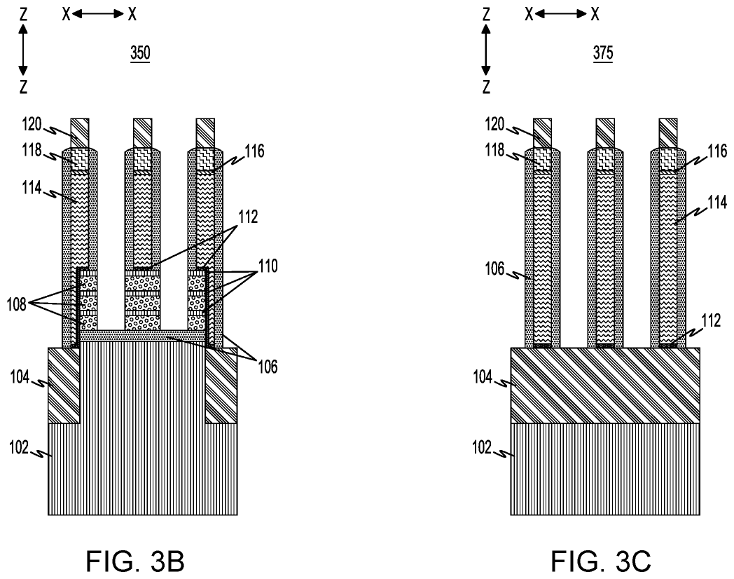

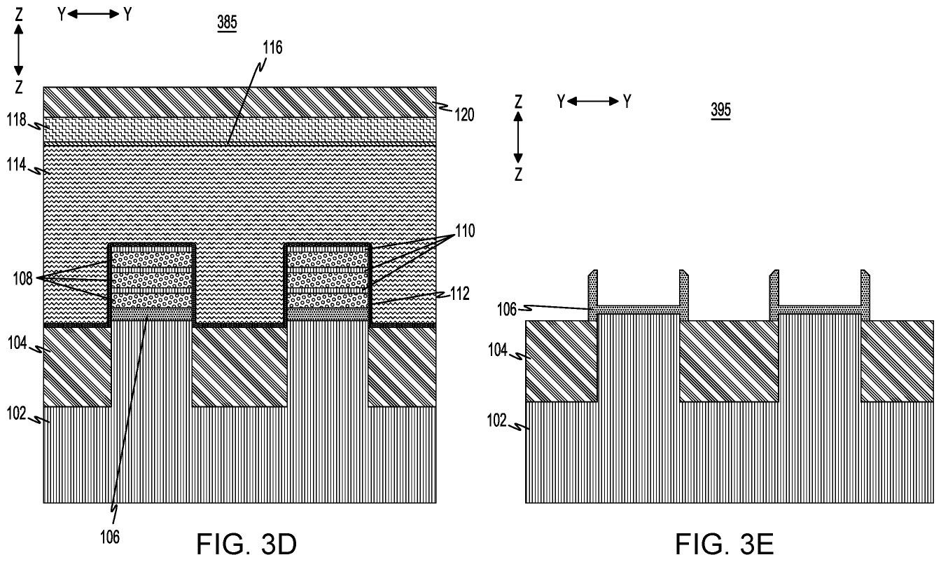

FIG. 3A shows a perspective view 300 of the structure of FIGS. 2A-2E following etching of exposed portions of the nanosheet stacks, and FIGS. 3B, 3C, 3D and 3E show respective cross-sectional views 350, 375, 385 and 395 of the structure of FIGS. 2A-2E following the etching of the exposed portions of the nanosheet stacks. The cross-sectional views 350 of FIG. 3B and 375 of FIG. 3C are taken in the X direction. More particularly, the cross-sectional view 350 of FIG. 3B represents an nFET or pFET cut view, and the cross-sectional view 375 of FIG. 3C is taken in the space between two nanosheet stacks (e.g., which may be between a first nanosheet stack used for an nFET device and a second nanosheet stack used for a pFET device, or between first and second nanosheet stacks which are both used for nFET or pFET devices). The cross-sectional views 385 of FIG. 3D and 395 of FIG. 3E are taken in the Y direction. More particularly, the cross-sectional view 385 of FIG. 3D is taken along where a gate region is formed, while the cross-sectional view 395 of FIG. 3E is taken between where two gate regions will be formed (e.g., in regions where source/drain regions will be formed).

As shown in FIGS. 3B and 3E, portions of the nanosheet stacks which are exposed by etching of the spacer layer 106 are removed (e.g., using any suitable etch processing).

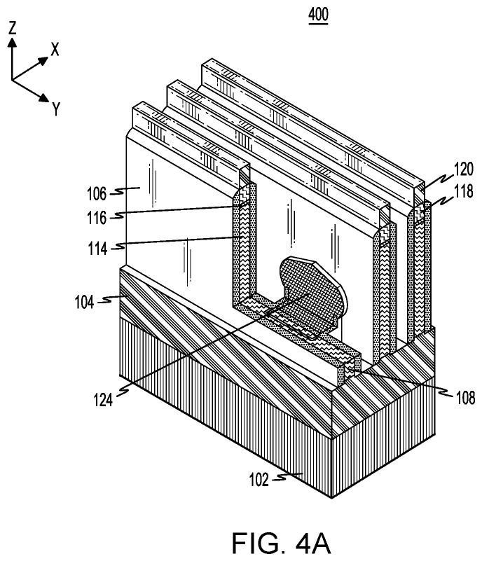

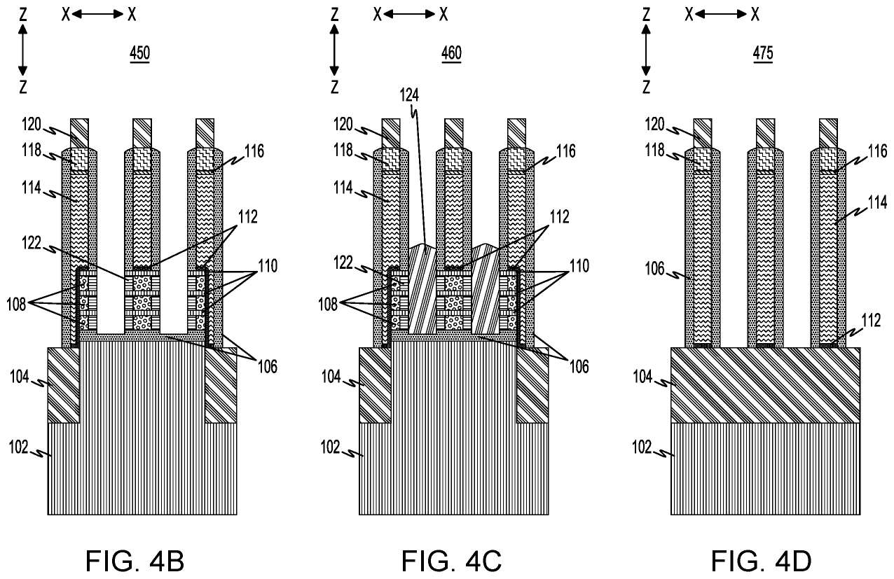

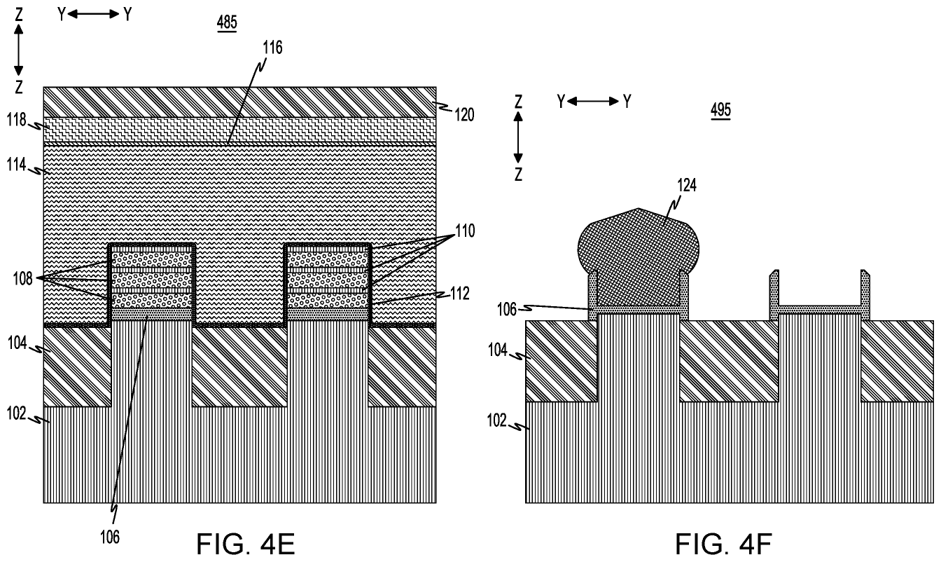

FIG. 4A shows a perspective view 400 of the structure of FIGS. 3A-3E following formation of first source/drain regions 124, and FIGS. 4B, 4C, 4D, 4E and 4F show respective cross-sectional views 450, 460, 475, 485 and 495 of the structure of FIGS. 3A-3E following the formation of the first source/drain regions. The cross-sectional views 450 of FIG. 4B, 460 of FIG. 4C and 475 of FIG. 4D are taken in the X direction. More particularly, the cross-sectional view 450 of FIG. 4B represents one of an nFET and pFET cut view, the cross-sectional view 460 of FIG. 4C represents the other one of the nFET and pFET cut view, and the cross-sectional view 475 of FIG. 4D is taken in the space between adjacent pairs of nFET or pFET devices. For ease of illustration, in the description below it is assumed that the cross-sectional view 450 of FIG. 4B is an nFET cut view while the cross-sectional view 460 of FIG. 4C is a pFET cut view and the cross-sectional view 475 of FIG. 4D is taken between adjacent pairs of pFET devices. The cross-sectional views 485 of FIG. 4E and 495 of FIG. 4F are taken in the Y direction. More particularly, the cross-sectional view 485 of FIG. 4E is taken along where a gate region is formed, while the cross-sectional view 495 of FIG. 4F is taken between where two gate regions are formed (e.g., in regions where source/drain regions will be formed).

Prior to formation of the first source/drain regions 124, an indent etch is performed to remove portions of the sacrificial layers 108. Inner spacers 122 are then formed in the indent regions as shown in FIGS. 4B and 4C. The inner spacers 122 may be formed of SiN, SiBCN, SiOCN, etc. The inner spacers 122 may have a width (in direction X) in the range of 5-20 nm.

The first source/drain regions 124 (e.g., pFET source/drain regions), are then formed using an epitaxial growth process. The first source/drain regions 124 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). In some embodiments, the epitaxial growth process used for forming the first source/drain regions 124 comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³.

After the first source/drain regions 124 are formed, a block mask may be formed followed by growth of second source/drain regions (not shown) for the other type of devices. Continuing with the example above where the first source/drain regions 124 are for pFET devices, the second source/drain regions would be formed for nFET devices. It should be appreciated, however, that this ordering may be reversed (e.g., source/drain regions for nFET devices may be formed before source/drain regions for pFET devices).

The remaining spacer layer 106 on sidewalls of the nanosheet stacks (as shown in FIG. 2E, where the spacer layer 106 etch exposes regions 201 of the sidewalls of the nanosheet stacks) prevents epitaxial nucleation on the bottommost one of the nanosheet channel layers 110. If the spacer layer 106 were etched further (e.g., more spacer “pull-down”), a taller gate height is required (e.g., a thicker gate HM layer 118) to avoid exposing the dummy gate layer 114 during the spacer layer 106 etch. A taller gate height, however, may lead to gate bending or flop-over if the aspect ratio is too high. Thus, there is a need for techniques which enable the spacer pull-down without increasing the gate height.

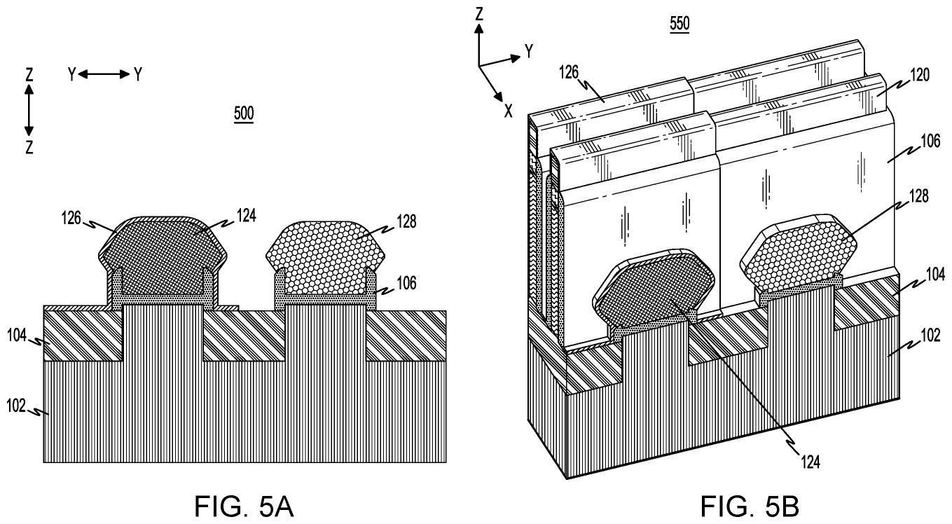

FIG. 5A shows a cross-sectional view 500 of the structure of FIGS. 4A-4E following formation of a protection layer 126 over the first source/drain regions 124, and following formation of second source/drain regions 128. The first source/drain regions 124, as noted above, are assumed to be pFET source/drain regions. The second source/drain regions 128 are assumed to be nFET source/drain regions. The second source/drain regions 128 may be formed of similar materials and with similar processing as that described above with respect to the first source/drain regions 124.

In the structure of FIG. 5A, it is assumed that the spacer layer 106 is not pulled down further. FIG. 5B shows a perspective view 550 of a structure that simulates formation with further pull-down or etching of the spacer layer 106. As illustrated in FIG. 5B, the further pull-down or etching of the spacer layer 106 may help for better nucleation on the first source/drain regions 124 and the second source/drain regions 128 on the bottom-most one of the nanosheet channel layers 110. However, without the remaining spacer layer 106 on the sides of the nanosheet stacks (e.g., as illustrated in FIG. 2E), there is more room for lateral epitaxial growth which requires increased nFET to pFET spacing and provides a device area penalty. In both FIGS. 5A and 5B, the first source/drain regions 124 and the second source/drain regions 128 are “symmetric” (e.g., the epitaxial growth is on both sides of the remaining spacer layer 106).

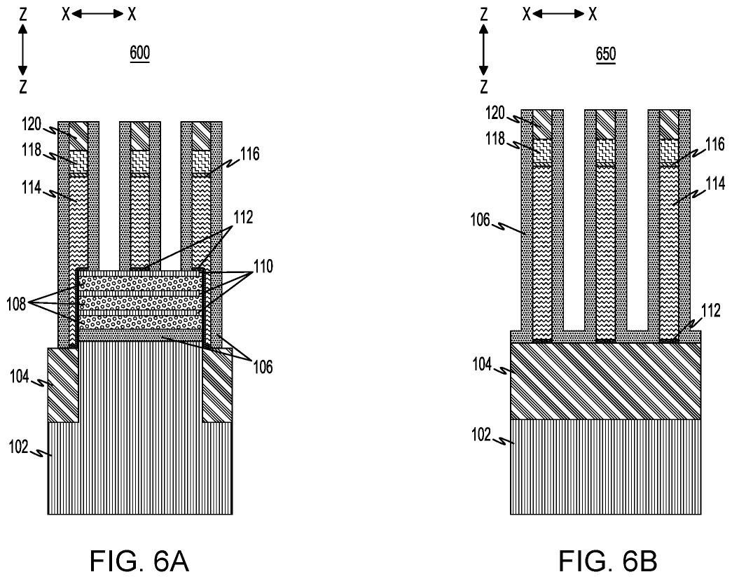

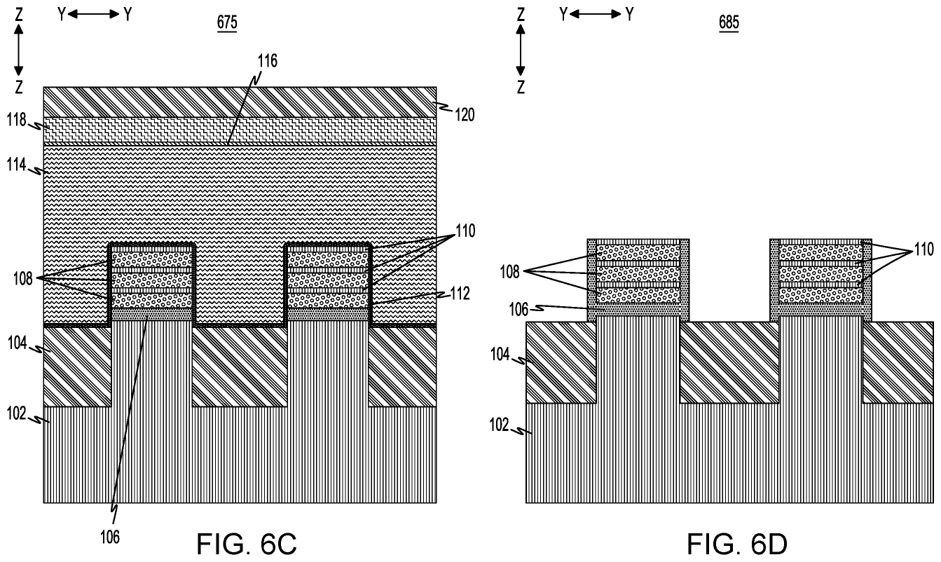

FIGS. 6A-6D shows cross-sectional views 600, 650, 675 and 685 of the structure of FIGS. 1A-1E following a recess of the spacer layer 106, where the spacer layer 106 remains on sidewalls of the nanosheet stacks (rather than being recessed a distance below tops of the nanosheet stacks as shown in FIG. 2E). The cross-sectional views 600 of FIG. 6A and 650 of FIG. 6B are taken in the X direction similar to the cross-sectional views 250 of FIG. 2B and 275 of FIG. 2C. The cross-sectional views 675 of FIG. 6C and 685 of FIG. 6D are taken in the Y direction similar to the cross-sectional views 285 of FIG. 2D and 295 of FIG. 2E.

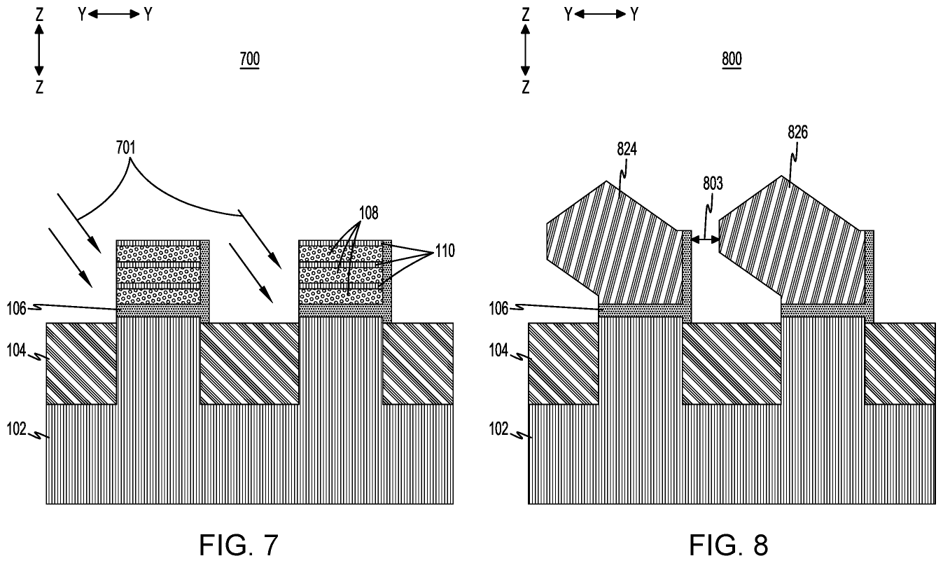

FIG. 7 shows a cross-sectional view 700 of the structure of FIGS. 6A-6D following an angled etch 701 which removes portions of the spacer layer 106 that are formed on one side of the nanosheet stacks. The angled etch 701 may comprise an angled reactive-ion etching (ME) process. A block mask may be formed over portions of the structure where the angled etch 701 is not necessary (e.g., regions of the structure where static random-access memory (SRAM) devices are to be formed).

Various tools may be used to perform an angled ME process. Using conventional lithography and etching, there is a limit to how close features may be brought together. In a horizontal direction this limit is referred to as a minimum pitch, and in a vertical direction this limit may be referred to as a minimum tip-to-tip distance. With extreme ultraviolet (EUV) lithography, the minimum pitch is approximately 36 nm while the minimum tip-to-top distance is approximately 40 nm. If smaller distances are needed for a design, extra patterning steps (e.g., added cut or block masks, additional EUV lithography etch steps, etc.) are used. Conventionally, etching is performed top-down. Angled RIE processes provide a lateral etch technique which allows etching at an angle (e.g., a 45 degree angle). By controlling the angle and direction of etch, a critical dimension (CD) may be maintained in one direction while shrinking the CD in another direction. Thus, as shown in the cross-sectional view 700 of FIG. 7, the angled etch 701 can remove portions of the spacer layer 106 from first sides of the nanosheet stacks but not second sides.

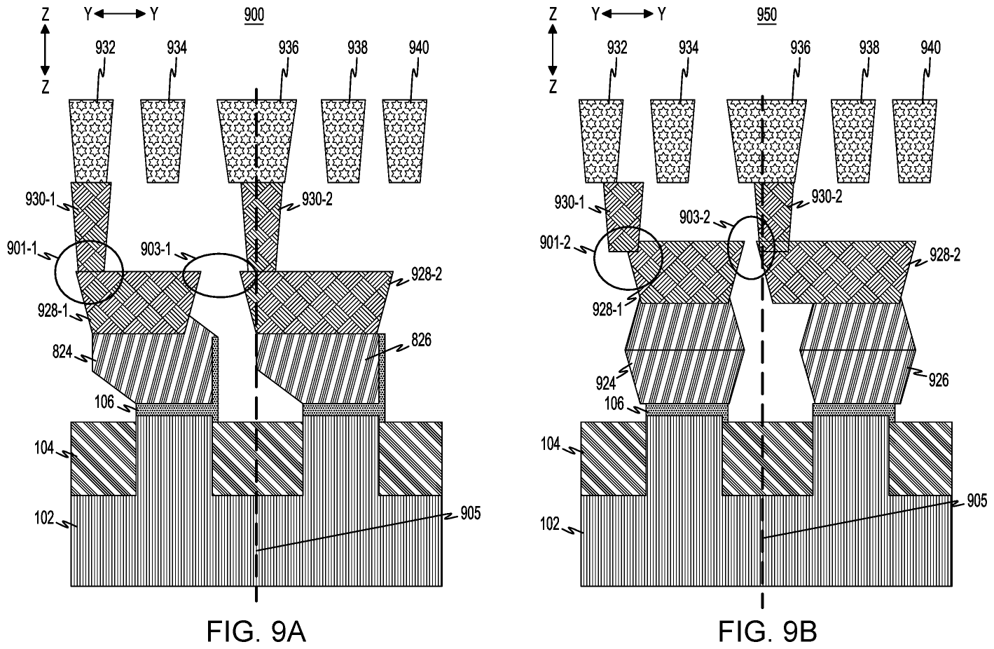

FIG. 8 shows a cross-sectional view 800 of the structure of FIG. 7 following epitaxial growth of first and second source/drain regions 824 and 826. The first and second source/drain regions 824 and 826 may be formed using similar materials and processing as that described above with respect to first source/drain regions 124. Here, the first and second source/drain region 824 and 826 are asymmetric, in that the growth is increased towards one side of the nanosheet stacks (e.g., the side that the spacer layer 106 was removed from by the angled etch 701). With the spacer layer 106 remaining on one side of the nanosheet stacks, the spacing 803 (e.g., an nFET to pFET spacing) may be reduced without risking shortage between the first and second source/drain regions 824 and 826. Removing the spacer layer 106 on one side of the nanosheet stacks also enables better nucleation of the first and second source/drain region 824 and 826. As will be described in further detail below with respect to FIGS. 9A and 9B, this also advantageously enables improved contact margins for interconnects through shifting the locations of the first and second source/drain regions 824 and 826 towards a middle of the spacing between adjacent nanosheet stacks.

FIG. 9A shows a cross-sectional view 900 of the FIG. 8 structure following formation of interconnect structures. The cross-sectional view 900 of FIG. 9A, similar to the cross-sectional views 700 of FIG. 7 and 800 of FIG. 8, is taken in the Y direction between gate regions where the first and second source/drain regions 824 and 826 are formed. FIG. 9B shows a cross-sectional view 950 illustrating a structure similar to that of FIG. 5A where an angled etch is not performed and the spacer layer 106 remains on both sides of the nanosheet stacks prior to formation of first and second source/drain regions 924 and 926. The structure of FIG. 9B thus represents one in which “symmetric” source/drain regions (e.g., first and second source/drain regions 924 and 926) are formed, as compared with the structure of FIG. 9A which includes “asymmetric” source/drain regions (e.g., first and second source/drain regions 824 and 826).

In both FIGS. 9A and 9B, the interconnect structures include first and second source/drain contacts 928-1 and 928-2 (collectively, source/drain contacts 928), first and second vias 930-1 and 930-2 (collectively, vias 930), and a signal and power network including signal lines 932, 934, 938 and 940 along with a power rail 936. The first source/drain contact 928-1 connects to the first source/drain region 824 in the structure of FIG. 9A, and to the first source/drain region 924 in the structure of FIG. 9B. The second source/drain contact 928-2 connects to the second source/drain region 826 in the structure of FIG. 9A, and to the second source/drain region 926 in the structure of FIG. 9B. As shown in FIG. 9A, the signal line 932 (which may also or alternatively function as a power rail) is connected to the first source/drain region 824 through the via 930-1 and the first source/drain contact 928-1 and the power rail 936 is connected to the second source/drain region 826 through the via 930-2 and the second source/drain contact 928-2. Similarly, as shown in FIG. 9B, the signal line 932 is connected to the first source/drain region 924 through the via 930-1 and the first source/drain contact 928-1 and the power rail 936 is connected to the second source/drain region 926 through the via 930-2 and the second source/drain contact 928-2.

The epitaxial growth of the first and second source/drain regions 824 and 826 following the angled etch 701 allows for improved contact margins between the vias 930-1 and 930-2 and the first and second source/drain contacts 928-1 and 928-2 in the structure of FIG. 9A relative to the structure of FIG. 9B, as highlighted in regions 901-1 and 901-2. As highlighted in regions 903-1 and 903-2, there is also improved spacing between the first and second source/drain contacts 928-1 and 928-2 in the structure of FIG. 9A relative to the structure of FIG. 9B. The power rail 936 falls in a middle between adjacent nanosheet stacks, as illustrated by the dashed line 905. The adjacent nanosheet stacks may both be used for pFET devices, may both be used for nFET devices, or one may be used for an nFET device while the other is used for a pFET device.

Illustrative embodiments provide semiconductor structures with asymmetric source/drain regions. For example, a semiconductor structure may include one or more source/drain regions which have a spacer (e.g., a gate spacer) remaining on side thereof. The source/drain region epitaxial formation is shifted to one side (e.g., where the gate spacer is removed) and placed closer to an adjacent nanosheet stack. Thus, the source/drain regions are asymmetric. Interconnects of the semiconductor structure also include source/drain contacts and vias which are shifted towards a middle of the spacing between nanosheet stacks (e.g., between nFET and pFET devices). Such structures may be formed by performing a gate spacer pull-back, followed by an angled etch (e.g., angled RIE) to remove the gate spacer on one side of nanosheet stacks. Further, source/drain contacts and vias connecting to the source/drain contacts may be shifted to the middle of a spacing between adjacent devices.

With the protection spacer remaining on one side of the source/drain regions, spacing (e.g., between adjacent devices) may be reduced without shortage between source/drain regions of adjacent devices. Further, the asymmetric source/drain regions allow for increased contact margin between source/drain contacts and vias which connect to signal and power lines. Thus, the structures described herein solve critical issues for nanosheet source/drain epitaxial formation and provide improved back-end-of-line (BEOL) interconnects for advanced technology nodes.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductors (CMOS s), metal-oxide-semiconductor field-effect transistors (MOSFETs), and/or fin field-effect transistors (FinFETs). By way of non-limiting example, the semiconductor devices can include, but are not limited to CMOS, MOSFET, and FinFET devices, and/or semiconductor devices that use CMOS, MOSFET, and/or FinFET technology.

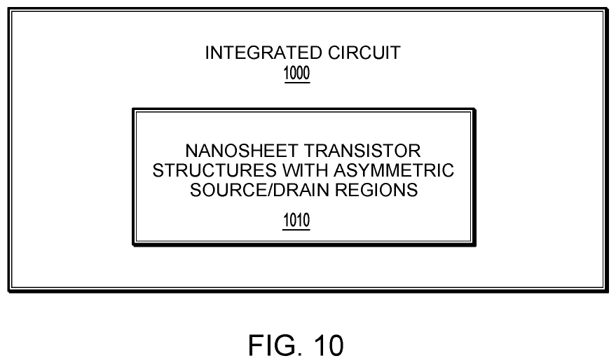

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 10 shows an example integrated circuit 1000 which includes one or more nanosheet transistor structures 1010 with asymmetric source/drain regions.

In some embodiments, a semiconductor structure comprises a source/drain region, a spacer layer on a first side of the source/drain region, a contact on a top surface of the source/drain region, and a via connected to a portion of the contact at a second side of the source/drain region, the second side of the source/drain region being opposite the first side of the source/drain region.

The source/drain region may be for a nanosheet transistor, and the spacer layer on the first side of the source/drain region may be at a first edge of a gate of the nanosheet transistor. The source/drain region may extend past a second edge of the gate of the nanosheet transistor, the second edge being on an opposite side of the gate as the first edge.

The source/drain region may comprise an asymmetrical source/drain region. The asymmetrical source/drain region may extend on the second side from a first nanosheet stack of a first nanosheet transistor towards a second nanosheet stack of a second nanosheet transistor adjacent the first nanosheet transistor. The asymmetrical source/drain region may not extend past the spacer layer on the first side.

The asymmetrical source/drain region may be adjacent nanosheet channel layers of a nanosheet stack, the first side of the asymmetrical source/drain region extending a first distance from a center of the nanosheet channel layers of the nanosheet stack towards the spacer layer, the second side of the asymmetrical source/drain region extending a second distance from a center of the nanosheet channel layers of the nanosheet stack. The first distance may be less than the second distance.

The source/drain region may extend asymmetrically from a center of nanosheet channel layers of a nanosheet transistor.

The via may interconnect the contact with a power rail.

In some embodiments, a semiconductor structure comprises a first transistor comprising a first source/drain region, a second transistor comprising a second source/drain region, and a spacer layer on a first side of the first source/drain region and a first side of the second source/drain region. A second side of the first source/drain region extends towards the first side of the second source/drain region.

The first transistor and the second transistor may comprise respective nanosheet transistors.

The first source/drain region may extend asymmetrically from a center of nanosheet channel layers of the first transistor. The first source/drain region may extend a first distance in a first direction from the center of the nanosheet channel layers of the first transistor towards the spacer layer on the first side of the first source/drain region and may extend a second distance in a second direction opposite the first direction from the center of the nanosheet channel layers of the first transistor towards the spacer layer on the first side of the second source/drain region. The second distance may be greater than the first distance.

In some embodiments, an integrated circuit comprises a nanosheet transistor structure comprising two or more nanosheet transistors, a first one of the two or more nanosheet transistors comprising a first source/drain region and a second one of the two or more nanosheet transistors comprising a second source/drain region, the second nanosheet transistor being adjacent the first nanosheet transistor, and a spacer layer on a first side of the first source/drain region and a first side of the second source/drain region. A second side of the first source/drain region extends towards the first side of the second source/drain region.

The first source/drain region may extend asymmetrically from a center of nanosheet channel layers of the first nanosheet transistor. The first source/drain region may extend a first distance in a first direction from the center of the nanosheet channel layers of the first nanosheet transistor towards the spacer layer on the first side of the first source/drain region and may extend a second distance in a second direction opposite the first direction from the center of the nanosheet channel layers of the first nanosheet transistor towards the spacer layer on the first side of the second source/drain region. The second distance may be greater than the first distance.

The integrated circuit may further comprise a contact on a top surface of the first source/drain region and a via connected to a portion of the contact at a second side of the first source/drain region.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a source/drain region;
a spacer layer on a first side of the source/drain region;
a contact on a top surface of the source/drain region; and
a via connected to a portion of the contact at a second side of the source/drain region, the second side of the source/drain region being opposite the first side of the source/drain region.

2. The semiconductor structure of claim 1, wherein the source/drain region is for a nanosheet transistor, and wherein the spacer layer on the first side of the source/drain region is at a first edge of a gate of the nanosheet transistor.

3. The semiconductor structure of claim 2, wherein the source/drain region extends past a second edge of the gate of the nanosheet transistor, the second edge being on an opposite side of the gate as the first edge.

4. The semiconductor structure of claim 1, wherein the source/drain region comprises an asymmetrical source/drain region.

5. The semiconductor structure of claim 4, wherein the asymmetrical source/drain region extends on the second side from a first nanosheet stack of a first nanosheet transistor towards a second nanosheet stack of a second nanosheet transistor adjacent the first nanosheet transistor.

6. The semiconductor structure of claim 5, wherein the asymmetrical source/drain region does not extend past the spacer layer on the first side.

7. The semiconductor structure of claim 4, wherein the asymmetrical source/drain region is adjacent nanosheet channel layers of a nanosheet stack, the first side of the asymmetrical source/drain region extending a first distance from a center of the nanosheet channel layers of the nanosheet stack towards the spacer layer, the second side of the asymmetrical source/drain region extending a second distance from a center of the nanosheet channel layers of the nanosheet stack.

8. The semiconductor structure of claim 7, wherein the first distance is less than the second distance.

9. The semiconductor structure of claim 1, wherein the source/drain region extends asymmetrically from a center of nanosheet channel layers of a nanosheet transistor.

10. The semiconductor structure of claim 1, wherein the via interconnects the contact with a power rail.

11. A semiconductor structure comprising:
a first transistor comprising a first source/drain region;
a second transistor comprising a second source/drain region; and
a spacer layer on a first side of the first source/drain region and a first side of the second source/drain region;
wherein a second side of the first source/drain region extends towards the first side of the second source/drain region.

12. The semiconductor structure of claim 11, wherein the first transistor and the second transistor comprise respective nanosheet transistors.

13. The semiconductor structure of claim 11, wherein the first source/drain region extends asymmetrically from a center of nanosheet channel layers of the first transistor.

14. The semiconductor structure of claim 13, wherein the first source/drain region extends a first distance in a first direction from the center of the nanosheet channel layers of the first transistor towards the spacer layer on the first side of the first source/drain region and extends a second distance in a second direction opposite the first direction from the center of the nanosheet channel layers of the first transistor towards the spacer layer on the first side of the second source/drain region.

15. The semiconductor structure of claim 14, wherein the second distance is greater than the first distance.

16. An integrated circuit comprising:
a nanosheet transistor structure comprising:
two or more nanosheet transistors, a first one of the two or more nanosheet transistors comprising a first source/drain region and a second one of the two or more nanosheet transistors comprising a second source/drain region, the second nanosheet transistor being adjacent the first nanosheet transistor; and
a spacer layer on a first side of the first source/drain region and a first side of the second source/drain region;
wherein a second side of the first source/drain region extends towards the first side of the second source/drain region.

17. The integrated circuit of claim 16, wherein the first source/drain region extends asymmetrically from a center of nanosheet channel layers of the first nanosheet transistor.

18. The integrated circuit of claim 17, wherein the first source/drain region extends a first distance in a first direction from the center of the nanosheet channel layers of the first nanosheet transistor towards the spacer layer on the first side of the first source/drain region and extends a second distance in a second direction opposite the first direction from the center of the nanosheet channel layers of the first nanosheet transistor towards the spacer layer on the first side of the second source/drain region.

19. The integrated circuit of claim 18, wherein the second distance is greater than the first distance.

20. The integrated circuit of claim 16, further comprising a contact on a top surface of the first source/drain region and a via connected to a portion of the contact at a second side of the first source/drain region.
